(19) United States
(12) Patent Application Publication
(10) Pub. No.: US 2012/0248422 A1
(43) Pub. Date: Oct. 4, 2012

(54) OPTICAL SEMICONDUCTOR DEVICE AND MANUFACTURING METHOD THEREOF

(75) Inventors: Toshiyuki MINE, Fussa (JP); Masaaki Fujimori, Kodaira (JP); Naofumi Ohashi, Tokyo (JP)

(73) Assignees: HITACHI KOKUSAI ELECTRIC INC.; HITACHI HIGH-TECHNOLOGIES CORPORATION

(21) Appl. No.: 13/432,678

(22) Filed: Mar. 28, 2012

(30) Foreign Application Priority Data
Apr. 1, 2011 (JP) JP2011-081553

(51) Int. Cl. H01L 51/52; H01L 51/56

(52) U.S. Cl. 257/40; 438/46; 257/E51.018; 257/E51.019

(57) ABSTRACT

In a device having an anode electrode, an organic EL layer, and a cathode electrode formed on a substrate in this order from a main surface side of the substrate, and an encapsulating film provided on the substrate so as to cover the emission layer, the encapsulating film includes a laminated film obtained by alternately laminating buffer films serving as flattening films and barrier films having high moisture barrier property, and the flattening film and the barrier film include a silicon oxynitride film. In the manufacturing process of the device, the buffer film including silicon oxynitride is formed by an optical CVD method using vacuum ultraviolet light, and in this process, radical irradiation by remote plasma is performed during the irradiation of the vacuum ultraviolet light.

### CROSS-REFERENCE TO RELATED APPLICATION

The present application claims priority from Japanese Patent Application No. 2011-081553 filed on Apr. 1, 2011, the content of which is hereby incorporated by reference to this application.

### TECHNICAL FIELD OF THE INVENTION

The present invention relates to an optical semiconductor device and a manufacturing method thereof, and in particular, to an encapsulating film of an overall organic EL element and a manufacturing method thereof.

### BACKGROUND OF THE INVENTION

An organic electroluminescence (hereinafter, organic EL) element has many merits such as low power consumption, self-luminescence, and high-speed response, and the development of the organic EL has been pursued for the application to a flat panel display (FPD) or lighting equipment. Further, a bendable display device can be achieved by using a flexible substrate such as a resin substrate (including a resin film), and new added values such as lightness in weight and unbreakability are created, and the application to flexible equipment has also been considered.

Since the organic EL element reduces its luminous efficiency and life when it contacts moisture or oxygen, it is necessary to form an encapsulating film in an environmental atmosphere where moisture and oxygen are eliminated from the manufacturing process. On the other hand, in a flexible substrate such as the resin substrate, a dimension change associated with the absorption of moisture needs to be suppressed, and for this reason, the encapsulating film is formed on the front and back of the resin substrate.

The encapsulating film of the organic EL is required not only to prevent diffusion of moisture and oxygen, but also to have (1) low-temperature film formation (to prevent deterioration of organic EL), (2) low-damage (to prevent deterioration of organic EL), (3) low-stress, low-Young's modulus (to prevent peeling), (4) high transmittance (to prevent deterioration of brightness), and the like. A thin film laminating method has been drawing attention as an encapsulating method. In the thin film laminating method, five to ten layers of a plurality of thin films different in purposes are formed. In general, a thin film with high film density is used as the encapsulating film in order to suppress diffusion of moisture or oxygen and the like. Specifically, a silicon nitride film and an alumina film are the representative films thereof. Since these films are hard (high in Young's modulus) and also high in film stress, there is a problem that the film is peeled off and a crack occurs if a thick film is used. For this reason, the laminated structure with a thin film (buffer film) to reduce the stress of the encapsulating film has been studied. Characteristics required for the buffer film are excellent flattening performance for an underlying material, superior embedding performance to suppress influences of foreign matters adhered on the surface, softness of the film (small in Young' modulus), and small film stress.

Meanwhile, as the manufacturing method of the encapsulating film, various types of film formation methods are proposed such as a plasma CVD (Chemical Vapor Deposition) method, an optical CVD method, a sputtering method and an evaporation method. The representative methods thereof include an optical CVD method using a vacuum ultraviolet light, in which an encapsulating film and a buffer film are continuously formed by using the same technique. Patent Document 1 (Japanese Unexamined Patent Application Publication No. 2005-63850) discloses a manufacturing method of an encapsulating film using the optical CVD method.

Patent Document 1 discloses a top emission type organic EL display panel, in which an encapsulating film including a vacuum ultraviolet light CVD film is formed on a substrate having an anode electrode, an organic EL layer, and a cathode electrode, a transparent electrode is provided on an emission layer (organic EL layer) formed on the substrate, and a light is extracted above the emission layer. Patent Document 1 is characterized in that the vacuum ultraviolet light CVD film includes a silicon oxide film, a silicon nitride film or a laminated film thereof, and a method of forming the encapsulating film directly on the cathode electrode is described therein.

Here, as a source gas which forms a silicon oxide film, the gas containing methyl group, ethyl group, silicon (Si), oxygen (O) and hydrogen (H) is used. For example, TEOS (Tetra ethoxy silane), HMDSO (Hexa methyl disiloxane), TMCTS (Tetra methyl cyclotetrasiloxane) or OMCTS (Octo methyl cyclotetrasiloxane) and the like are used. Further, as a source gas which forms a silicon nitride film, the gas containing methyl group, silicon (Si), nitrogen (N) and hydrogen (H) is used. For example, BTBAS (Bis(tertiary butyl amino)silane) is used.

### SUMMARY OF THE INVENTION

The organic EL display panel described in Patent Document 1 uses a laminated structure of a silicon oxide film and a silicon nitride film as an encapsulating film. However, since the silicon oxide film and the silicon nitride film are greatly different from each other in terms of refractive index, the laminated film thereof has a problem that a reflection of visible light occurring at the interface between these films constituting the laminated film is large. More specifically, when the encapsulating film composed of a silicon oxide film and a silicon nitride film is adopted for the top emission type organic EL display panel, since an extraction efficiency of the visible light emitted on the organic EL layer is small, there arises a problem that the brightness (light extraction efficiency) of the display is small.

Here, FIGS. 8 and 9 show cross-sectional views of the laminated structure of a silicon oxide film and a silicon nitride film, and FIGS. 10 and 11 show graphs of simulation results of reflectance of the laminated structure of a silicon oxide film and a silicon nitride film. The graphs of FIGS. 10 and 11 show the calculation results of light reflectance of the laminated structures of FIGS. 8 and 9, respectively, and show a value of reflectance of the vertical axis with respect to a value of the wavelength of the horizontal axis.

The lowermost layers of the laminated structures shown in FIGS. 8 and 9 are cathode electrodes 301 and 401 of the organic EL elements, respectively, and any of the cathode electrodes has the refractive index of 1.7 here. Also, the uppermost layers of the laminated structures shown in FIGS. 8 and 9 are adhesion layers (resin layer) 306 and 406, respectively, and any of the adhesion layers also has the refractive index of 1.7.

The laminated structure of FIG. 8 is obtained by sequentially laminating a silicon oxide film 302a, a silicon nitride film 302b, a silicon oxide film 303a, a silicon nitride film 303b, a silicon oxide film 304a, a silicon nitride film 304b, a silicon oxide film 305a and the adhesion layer 306 on the cathode electrode 301 in this order. Also, the laminated structure of FIG. 9 is obtained by sequentially laminating a silicon nitride film 402b, a silicon oxide film 402a, a silicon nitride film 403b, a silicon oxide film 403a, a silicon nitride film 404b, a silicon oxide film 404a, a silicon nitride film 405b, and the adhesion layer 406 on the cathode electrode 401 in this order. The refractive indexes of the silicon oxide films 302a to 305a shown in FIG. 8 and the silicon oxide films 402a to 404a shown in FIG. 9 are 1.45, and the refractive indexes of the silicon nitride films 302b to 304b shown in FIG. 8 and the silicon nitride films 402b to 405b shown in FIG. 9 are 2.0. Here, to simplify the calculation, the calculation is made under the assumption that the refractive index in each wavelength is constant and there is no light absorption by the silicon oxide film and the silicon nitride film.

The thicknesses of the silicon nitride films 302b to 304b and 402b to 405b are all 100 nm, the thicknesses of the silicon oxide films 302a and 402a of the lowermost layers are 1000 nm, and the thicknesses of the other silicon oxide films 303a to 305a, 403a and 404a are 500 nm.

In the laminated structure shown in FIG. 8, the films in contact with the cathode electrode 301 and the adhesion layer 306 are the silicon oxide films 302a and 305a, respectively, and in the laminated structure shown in FIG. 9, the films in contact with the cathode electrode 401 and the adhesion layer 406 are the silicon nitride films 402b and 405b, respectively.

As is evident from FIGS. 10 and 11, it is found that even if insertion positions of the silicon oxide film and the silicon nitride film are changed, a reflectance of light having the wavelength of 500 nm to 700 nm exceeds 50%. Since the transmittance of light is lowered as the reflectance becomes larger, when the encapsulating film including the silicon oxide film and the silicon nitride film as shown in FIGS. 8 and 9 is formed on the organic EL, the reflectance inside the encapsulating film exceeds 50%, and the brightness of the display device provided with the organic EL is lowered. This reflectance fluctuates a little due to the difference in the film thickness of each laminated film shown in FIGS. 8 and 9 and due to the difference in the refractive indexes of the cathode electrodes 301 and 401 or the adhesion layers 306 and 406, but no large differences are observed. In other words, it is found that the influence of multiple reflection occurring at each interface is particularly great in the laminated structure of the silicon oxide film and the silicon nitride film and the brightness of the display is significantly reduced by the multiple reflection inside the encapsulating film.

Further, from a viewpoint of moisture barrier property, that is, an ability of preventing the intrusion of moisture, generally, an inorganic film with a high film density has higher moisture barrier property. In Patent Document 1, at the time of forming the encapsulating film, particularly, the silicon nitride film, an organic silicon source is adopted. In the optical CVD using the organic silicon source, however, since the organic film containing a large amount of carbon (C) is formed, the deposited silicon nitride film has small film density. Hence, from a viewpoint of forming a moisture barrier film (barrier film), it is advantageous in terms of the reliability of the device to use the inorganic barrier film containing no carbon in the film rather than the barrier film containing carbon in the film.

Further, another big problem caused when forming an encapsulating film on the organic EL by using the optical CVD method using a vacuum ultraviolet light is the damage incurred on the organic EL by the vacuum ultraviolet light with a large photon energy. Although not shown in FIGS. 8 and 9, in the top emission type organic EL display, the organic EL is present directly below the cathode electrodes 301 and 401. The photon energy of the vacuum ultraviolet light is as large as about 7 eV or more, and even if it slightly transmits through the cathode electrodes, the organic EL suffers a great damage.

The cathode electrode is required to have a transmittance of 80% or more with respect to a visible light (400 nm to 700 nm). In a top emission type OLED (Organic Light Emitting Diode) display, an extremely thin metal film, for example, an alloy such as Al—Li or Ag—Mg is generally used. Although it is possible to suppress the vacuum ultraviolet light transmitting through the cathode electrode by increasing the thickness of the cathode electrode, when the cathode electrode is made thick, there arises a problem that a transmittance of visible light is significantly lowered.

Although descriptions have been made with taking the top emission type OLED display in which the light is extracted from the cathode electrode side as an example, the same problem arises also in the structure in which the cathode electrode and the anode electrode are reversely arranged and the light emission is performed from an indium oxide such as ITO (Indium Tin Oxide) based anode electrode and a zinc oxide such as AZO (Aluminum doped Zinc Oxide) based anode electrode. Consequently, to perform the thin-film encapsulation by the optical CVD method using the vacuum ultraviolet light, a technology capable of increasing a transmittance of visible light without giving any optical damage to the organic EL is necessary.

An object of the present invention is to reduce a reflectance of the encapsulating film of the optical semiconductor device and improve light extraction efficiency.

Further, another object of the present invention is to significantly suppress the optical damage to the organic EL by the optical CVD method at the time of forming the encapsulating film of the optical semiconductor device.

The above and other objects and novel characteristics of the present invention will be apparent from the description of the present specification and the accompanying drawings.

The following is a brief description of an outline of the typical invention disclosed in the present application.

An optical semiconductor device according to an invention of the present application is an optical semiconductor device having a first electrode, an organic emission layer, and a second electrode formed on a substrate in this order from a main surface side of the substrate, and an encapsulating film provided on the substrate so as to cover the emission layer, the encapsulating film includes a laminated film obtained by alternately laminating a flattening film and a barrier film, and the flattening film and the barrier film include a silicon oxynitride film.

Also, a manufacturing method of an optical semiconductor device according to an invention of the present application includes the steps of: (a) forming a first electrode on a substrate; (b) forming an organic emission layer electrically connected to the first electrode on the first electrode; (c) forming a second electrode electrically connected to the organic emission layer on the organic emission layer; and (d) forming a silicon oxynitride film on the organic emission layer by an optical CVD method using a vacuum ultraviolet light, and in the step (d), radical irradiation by remote plasma is performed during irradiation of the vacuum ultraviolet light.

The effects obtained by typical embodiments of the invention disclosed in the present application will be briefly described below.

According to the present invention, the light extraction efficiency of the optical semiconductor device can be improved.

### BRIEF DESCRIPTIONS OF THE DRAWINGS

FIG. 1 is a cross-sectional view of an optical semiconductor device of an embodiment of the present invention;

FIG. 2 is a cross-sectional view showing a manufacturing method of the optical semiconductor device of the embodiment of the present invention;

FIG. 3 is a cross-sectional view describing the manufacturing method of the optical semiconductor device continued from FIG. 2;

FIG. 4 is a cross-sectional view describing the manufacturing method of the optical semiconductor device continued from FIG. 3;

FIG. 5 is a schematic diagram of a film formation device used for the manufacturing process of the optical semiconductor device of the embodiment of the present invention;

FIG. 6 is a table for explaining configurations of the respective barrier film and buffer film of the embodiment of the present invention and comparison examples;

FIG. 7 is a cross-sectional view describing the manufacturing method of the optical semiconductor device continued from FIG. 4;

FIG. 8 is a cross-sectional view of a laminated structure shown as a comparison example;

FIG. 9 is a cross-sectional view of a laminated structure shown as a comparison example;

FIG. 10 is a graph showing reflectance with respect to wavelength in the laminated structure shown as a comparison example;

FIG. 11 is a graph showing reflectance with respect to wavelength in the laminated structure shown as a comparison example;

FIG. 12 is a graph describing the change of reflectance depending on the difference in the film configuration;

FIG. 13 is a graph describing the change of reflectance depending on the difference in the film configuration;

FIG. 14 is a graph describing the change of reflectance depending on the difference in the film configuration;

FIG. 15 is a graph showing a relationship between the refractive index difference of the buffer film and the barrier film and the maximum reflectance; and

FIG. 16 is a cross-sectional view of a laminated structure shown as a comparison example.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiments, and the repetitive description thereof will be omitted. In addition, the description of the same or similar portions is not repeated in principle unless particularly required in the following embodiments.

An embodiment of the present invention will be described below with reference to the drawings.

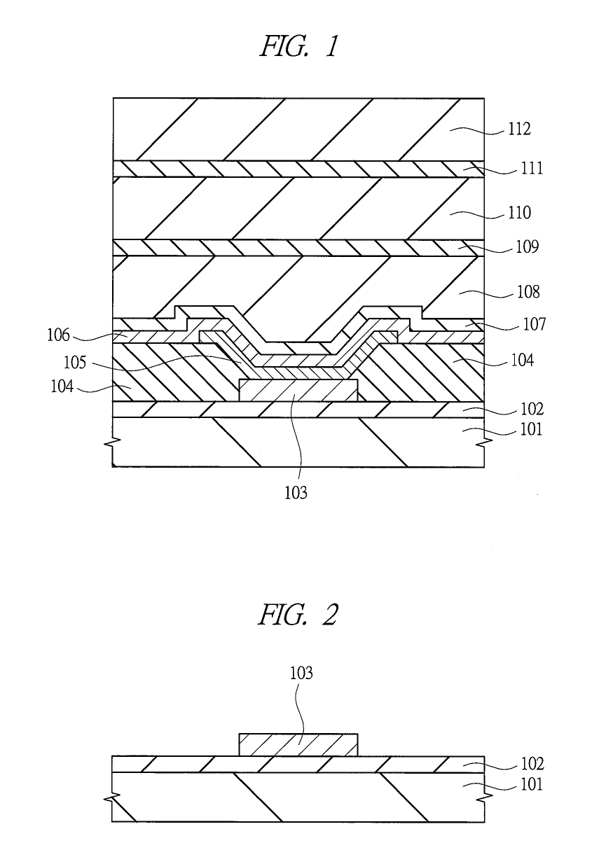

FIG. 1 shows a cross-sectional view of an optical semiconductor device including an organic EL element of the present embodiment. The organic EL element of the present embodiment has a glass substrate 101 as shown in FIG. 1, and an anode electrode 103 and a bank part 104 are formed on the glass substrate 101 via an insulating film 102. The glass substrate 101 contains, for example, quartz, and the insulating film 102 is made of a silicon oxide film. The bank part 104 is an insulating film made of photosensitive polyimide and it contacts an upper surface of the insulating film 102. The anode electrode 103 is a conductive layer made of, for example, a laminated film obtained by sequentially laminating aluminum and indium-tin-oxide (ITO) in this order, and it contacts the upper surface of the insulating film 102. The bank part 104 has an opening with a tapered angle, and an upper surface of the anode electrode 103 is exposed at the bottom of the opening. However, the side surfaces of the anode electrode 103 are covered with the bank part 104. Note that the case where a material of the glass substrate 101 is, for example, quartz has been described here, but the glass substrate 101 may be a resin substrate.

The bank part 104 mentioned here is an insulating film formed in the shape of a bank, has a bottom surface and an upper surface in parallel to each other, and is a trapezoidal film provided with side walls having a slant tapered angle with respect to the bottom surface and the upper surface.

An organic EL layer 105 is formed on the anode electrode 103 and the bank part 104. The organic EL layer 105 contacts the upper surface of the anode electrode 103 at the bottom of the opening, and is formed so as to cover the upper surface of the anode electrode 103 exposed from the opening, inner walls having the tapered angles of the opening, and a part of the upper surface of the bank part 104. The organic EL layer 105 is an emission layer made up of the laminated film composed of a hole injection layer, a hole transport layer, an emission layer, an electron transport layer, and an electron injection layer which are laminated from the anode electrode 103 side, and the laminated films will be collectively described as the organic EL layer 105 here.

On the organic EL layer 105 and the bank part 104, a cathode electrode 106 and a vacuum ultraviolet light absorption layer 107 are sequentially formed in this order from the glass substrate 101 side so as to cover the organic EL layer 105. The cathode electrode 106 is a conductive layer made of an Ag—Mg alloy having a thickness of about 20 nm. The vacuum ultraviolet light absorption layer 107 is formed so as to cover the cathode electrode 106, and further, is formed so as to overlap with the organic EL layer 105 in a plan view. More specifically, the vacuum ultraviolet light absorption layer 107 is formed right above the organic EL layer 105. Also, the vacuum ultraviolet light absorption layer 107 is formed of a silicon oxynitride film, and has a thickness of about 150 nm.

On the vacuum ultraviolet light absorption layer 107, a buffer film 108, a barrier film 109, a buffer film 110, a barrier film 111, and a buffer film 112 are formed in this order from the glass substrate 101 side. The buffer films 108, 110, and 112, and the barrier films 109 and 111 make up the encapsulating film, and the barrier film mainly functions as a barrier film for moisture. As shown in FIG. 1, a plurality of the buffer films and the barrier films are alternately laminated on the organic EL layer 105 in this order from the glass substrate 101 side. Since the barrier films 109 and 111 have higher film density than that of the buffer films 108, 110, and 112, the barrier films 109 and 111 are higher in moisture barrier property than the buffer films 108, 110, and 112. Here, the buffer films and the barrier films are collectively defined as the encapsulating film. Note that the encapsulating film described in the present application means a film for preventing moisture and oxygen from entering the organic EL layer and the resin substrate from the outside.

The buffer films 108, 110, and 112 have a function of flattening each upper surface and lower surface of a plurality of films which make up the encapsulating film. This is because the buffer films 108, 110, and 112 show a fluidity in the manufacturing process, and even if unevenness is formed on the ground of the buffer film 108 by the opening of the bank part 104, the upper surface of the buffer film 108 has a flat shape. In other words, even if the bottom surface of the buffer film 108 formed at the lowermost layer in the encapsulating film has unevenness, its upper surface is flattened. Further, the buffer films 108, 110, and 112 having lower Young's modulus than the barrier films 109 and 111 are flattening films which have a function of reducing the Young's modulus of the entire encapsulating film and preventing the occurrence of the peeling of the encapsulating film or the occurrence of the cracks of the encapsulating film.

Although not shown in FIG. 1, a contact plug and a wiring pad for electrically connecting to the outside are formed on the anode electrode 103 and the cathode electrode 106, respectively, and the voltage can be independently applied thereto, respectively. Each of the barrier films 109 and 111 has a thickness of about 150 nm, and each of the buffer films 108, 110, and 112 has a thickness of about 1000 nm.

Although any of the buffer films 108, 110, and 112 and the barrier films 109 and 111 which make up the organic EL element of the present embodiment is formed of a silicon oxynitride film, the organic EL element in which the buffer films 108, 110, and 112 and the barrier films 109 and 111 shown in FIG. 1 are formed of such members as a silicon oxide film and a silicon nitride film will also be described later for comparison.

The main characteristic of the optical semiconductor device of the present embodiment lies in that the buffer films 108, 110, and 112 contain an inorganic silicon oxynitride film formed by the optical CVD method using vacuum ultraviolet light. The effect of the optical semiconductor device of the present embodiment will be described below.

In the top emission type organic EL element which emits light through the cathode electrode and the encapsulating film on the upper part of the organic EL layer serving as the emission layer, it is considered that the encapsulating film formed on the organic EL layer has a laminated structure. The encapsulating film is required to have a barrier property to prevent moisture and the like from entering the element from the outside of the element. Further, the interface between each of the films constituting the laminated structure of the encapsulating film needs to have a high flatness in order to efficiently extract the light emitted from the organic EL layer. The bank part having the opening in which the upper surface of the organic EL layer is exposed is formed between the anode electrode having the organic EL layer thereon and the encapsulating film, and a large unevenness is formed on the upper surface of the bank part due to the opening. Further, the unevenness is sometimes formed on the bank part due to etching residue and the like. For this reason, it is important that the encapsulating film secures a barrier property of moisture and has a property to improve the flatness of the interface between the films which make up the laminated structure of the encapsulating film at the time of covering to fill the unevenness described above.

Therefore, it is considered that the encapsulating film has a structure in which the silicon nitride film which has good moisture barrier property and the silicon oxide film which is excellent in fluidity in its formation and is easily formed to have a flat upper surface after its formation are laminated. However, in the optical semiconductor device having the encapsulating film formed by laminating the silicon nitride film and the silicon oxide film in this manner, there arises a problem that the brightness of the organic EL element is reduced due to multiple reflection inside the encapsulating film.

The multiple reflection of the visible light emitted from the organic EL layer can be suppressed by reducing as much as possible the refractive index difference between a material of the layer on an incident side (cathode electrode) and the encapsulating film in contact with it, the refractive index difference between a material of the layer on an exit side (adhesion layer) and the encapsulating film in contact with it, and the refractive index difference between the laminated films in the encapsulating film. The incident side and the exit side mentioned here mean that a light emitted upward from the organic EL layer below the cathode electrode enters from the cathode electrode side (incident side) and is emitted to the adhesion layer side (exit side).

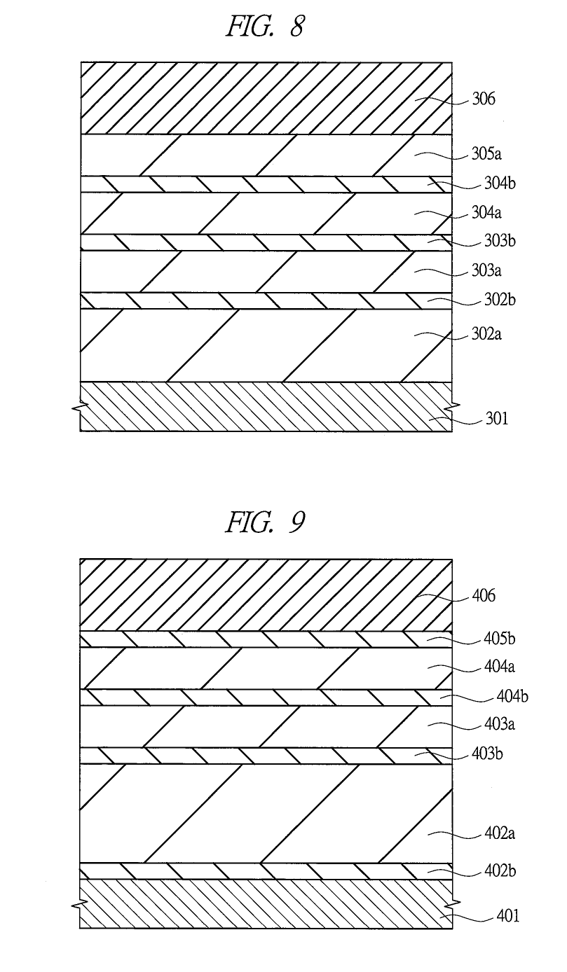

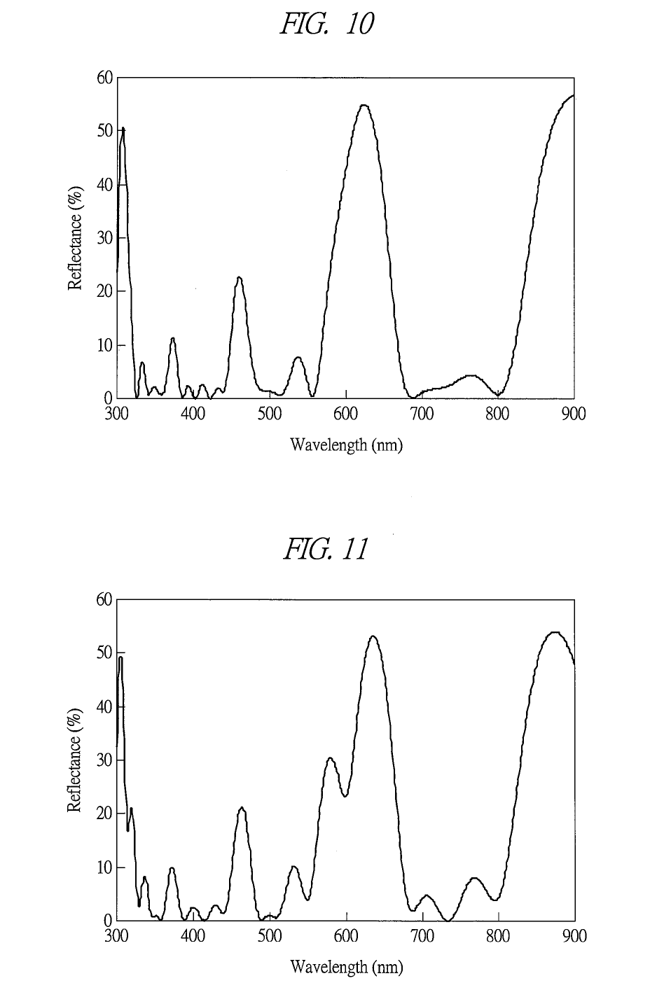

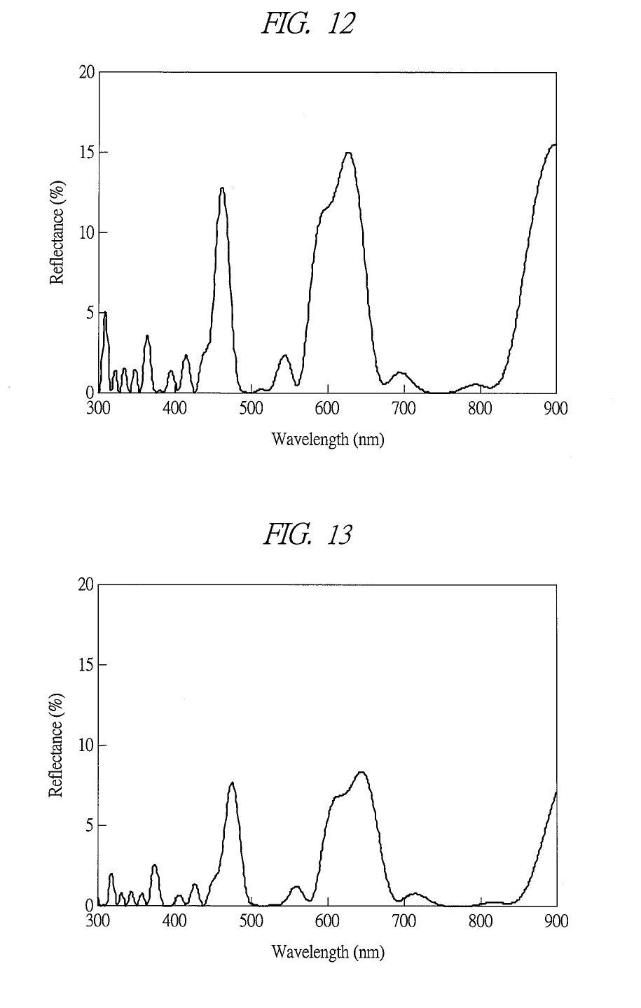

Here, FIGS. 12 to 14 show graphs which are the simulation results of reflectance of the laminated structure. These graphs show the calculation results of reflectance of the laminated structure shown in FIG. 8. The horizontal axis of each of the graphs represents the wavelength band of 300 nm to 900 nm, and the vertical axis represents reflectance when a light transmits through the inside of the laminated structure from the lower layer to the upper layer. FIG. 8 is a cross-sectional view of the laminated structure of a comparison example, and this laminated structure is obtained by sequentially laminating a silicon oxide film 302a, a silicon nitride film 302b, a silicon oxide film 303a, a silicon nitride film 303b, a silicon oxide film 304a, a silicon nitride film 304b, a silicon oxide film 305a, and an adhesion layer 306 in this order on the cathode electrode 301. Each of the cathode electrode 301 of the lowermost layer and the adhesion layer (resin layer) 306 of the uppermost layer of the laminated structure shown in FIG. 8 has the refractive index of 1.7. The silicon nitride films 302b, 303b, and 304b are barrier films to prevent the intrusion of moisture and the like, and the silicon oxide films 302a, 303a, 304a, and 305a are buffer films (flattening films) which have a function of improving a flatness of the entire encapsulating film and reducing the Young's modulus.

More specifically, since the buffer film has lower Young's modulus than that of the barrier film and has the fluidity during the manufacturing process, even if the ground of the region where the buffer film is formed has unevenness, the buffer film is formed so as to fill the unevenness, and the upper surface of the formed buffer film becomes flat.

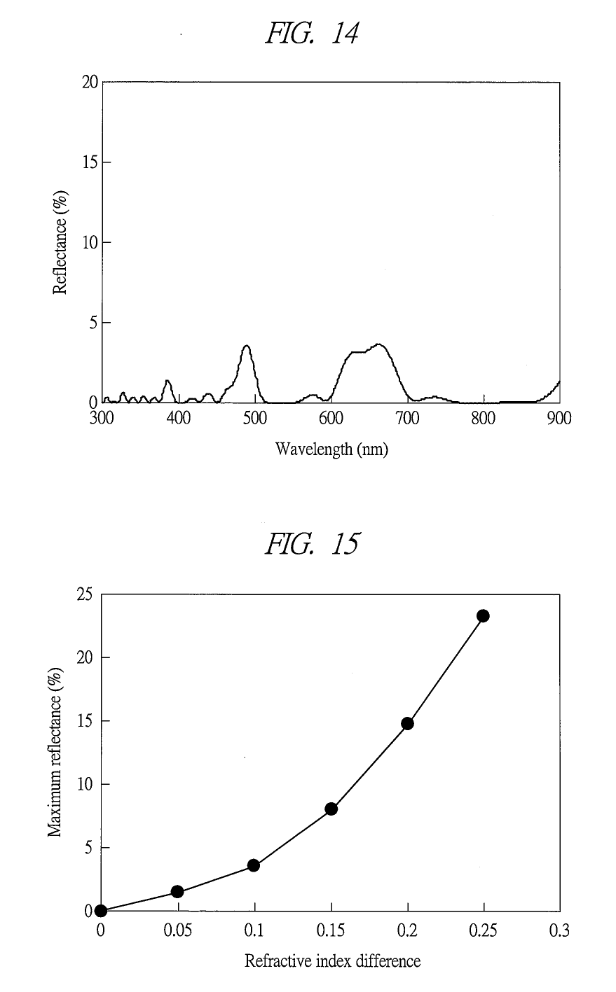

The graphs of FIGS. 12 to 14 show the simulation results calculated on the assumption that the refractive index of the silicon nitride films 302b, 303b, and 304b shown in FIG. 8 is 1.7. The horizontal axis represents a wavelength, and the vertical axis represents a reflectance. Also, these graphs show the results of calculation on the assumption that the refractive indexes of the silicon oxide films 302a, 303a, 304a and 305a are 1.5 in FIG. 12, 1.55 in FIG. 13, and 1.6 in FIG. 14, respectively. More specifically, from the graphs shown in FIGS. 12, 13, and 14, it is possible to know the change of the reflectance of the laminated structure observed when the refractive indexes of the silicon oxide films constituting the encapsulating film are brought close to the refractive indexes of the silicon nitride film, the cathode electrode, and the adhesion layer to reduce the refractive index difference therebetween. In other words, the refractive indexes of the silicon oxide films constituting the laminated structure calculated in FIG. 14 are close to the value of 1.7 which is the refractive indexes of the silicon nitride film, the cathode electrode, and the adhesion layer described above compared with the refractive indexes of the silicon oxide films constituting the laminated structure calculated in FIG. 12. Here, to simplify the calculation, the calculation is made under the assumption that the refractive index in each wavelength is constant and there is no light absorption by the thin film. It is found from the graphs of FIGS. 12 to 14 that when the refractive index difference of the laminated films is reduced, the reflectance is also reduced.

FIG. 15 shows the relationship between the refractive index difference of the laminated films used for encapsulation and the maximum reflectance of the laminated films. FIG. 15 is a graph showing the relationship of the maximum reflectance of the vertical axis with respect to the refractive index difference of the buffer film and the barrier film constituting the laminated film shown on the horizontal axis. As is evident from FIG. 15, when the refractive index difference is increased, the maximum reflectance is also increased. The numerical value of this reflectance is particularly greatly affected by the multiple reflection generated by the difference of the refractive indexes of the laminated films rather than the variation of the refractive indexes of the incident side material and the exit side material of the light, and the reflectance can be suppressed by reducing the refractive index difference.

For example, as means for setting the refractive indexes of the silicon oxide films constituting the encapsulating film to about 1.7, a method of having nitrogen contained in a silicon oxide film to form a silicon oxynitride film (SiON film) is generally used. However, in the optical CVD method using an organic source containing a large amount of carbon as a source gas, it is difficult to obtain a thin film with a high film density, that is, a moisture barrier film (barrier film) with a high barrier property for moisture. For this reason, it is desirable to use an inorganic film for the moisture barrier film of the laminated encapsulating film in view of the reliability.

Furthermore, when a silicon oxynitride film is formed by the optical CVD method using the vacuum ultraviolet light, a method of making an organic silicon based gas react with a gas serving as an oxidation source or a nitridation source is also available. However, since an ammonium gas (NH₃) or a nitrogen gas (N₂) serving as a source gas of nitrogen atom (N) and the like have small quenching cross-section area, a degradation efficiency by optical assist is small and it is extremely difficult to obtain the silicon oxynitride film having a desired composition. In other words, when the silicon oxynitride film is formed by the optical CVD method using the vacuum ultraviolet light, there is a problem that a desired amount of nitrogen is not introduced into the formed silicon oxynitride film, and it is difficult to bring the refractive index close to 1.7. Hence, in the present embodiment, in order to obtain excellent moisture barrier property while making use of an advantage of an optical CVD film such as lower stress and lower Young's modulus than a thermal CVD film or a plasma CVD film, the silicon oxynitride film (buffer film and barrier film) is formed by a remote plasma assist. The plasma assist means a film formation method in which a material is pre-degraded by plasma and supplied in a radical state, thereby depositing a film. In the present embodiment, the silicon oxynitride film is formed by using the optical CVD method using the source gas and the plasma assist in combination. Further, the surface to be treated (substrate) is disposed at a position apart from a plasma region (plasma zone) in order to separately use radicals, and this is referred to as remote plasma. Further, the pre-degradation of the material by plasma and the supply of the material in a radical state are referred to as radical irradiation here.

Specifically, in the formation of the buffer film, an organic silicon source containing carbon is used for the source gas of the optical CVD, and a nitrogen radical or a nitrogen radical and an oxygen radical formed by the remote plasma is introduced as a nitridation source. By this means, a SiON (silicon oxynitride) film utilizing the merit of the optical CVD film can be formed. On the other hand, in the formation of the SiON film having high barrier property, an inorganic silicon source not containing carbon such as high order silane is used as the source gas of the optical CVD, and the nitrogen radical or the nitrogen radical and the oxygen radical formed by the remote plasma is introduced as the nitridation source. By this means, an inorganic SiON film having high moisture barrier property can be formed. More specifically, the buffer films 108, 110, and 112 shown in FIG. 1 are organic silicon oxynitride films containing carbon, and the barrier films 109 and 111 are inorganic silicon oxynitride films containing no carbon. By constituting the barrier films 109 and 111 from the inorganic silicon oxynitride film containing no carbon, the barrier films 109 and 111 having high film density and high moisture barrier property can be formed.

The buffer films 108, 110, and 112 and the barrier films 109 and 111 are made of the silicon oxynitride films formed by using the optical CVD method using the vacuum ultraviolet light and the plasma CVD method using the remote plasma in combination. The method of forming the silicon oxynitride film by the optical CVD method using the remote plasma assist will be described later in details. The quenching cross-section area means a scale showing the ease of light absorption of a substance, and the substance having larger quenching cross-section area absorbs light more easily and is easily degraded in the optical CVD method.

In the optical semiconductor device of the present embodiment, when the laminated encapsulating film including the buffer film which has small film stress and small Young' modulus and is excellent in filling property and the barrier film having high moisture barrier property is formed, the refractive index difference between the buffer film and the barrier film is reduced as much as possible, and multiple reflection inside the laminated encapsulating film can be suppressed. Further, by reducing the refractive index difference between the films constituting the laminated encapsulating film, a light extraction efficiency of the optical semiconductor device can be significantly improved.

However, in the case where the encapsulating film is formed by the optical CVD method on the organic EL layer via the cathode electrode, there is a problem that the vacuum ultraviolet light irradiated when forming the encapsulating film transmits through the cathode electrode and reaches the organic EL layer to damage the organic EL layer, and the organic EL layer scarcely emits light. Photon energy of the vacuum ultraviolet light used in the film formation process of the optical CVD method is about 7 eV or more, and even if it slightly transmits through the cathode electrode, it gives a great damage to the organic EL layer.

The cathode electrode is required to have a transmittance of 80% or more for the visible light (400 nm to 700 nm). In the top emission type OLED display, it is considered that an extremely thin metal film, for example, such as an Al—Li alloy and an Ag—Mg alloy is used. As a method of suppressing the vacuum ultraviolet light that transmits through the cathode electrode, a method of increasing the thickness of the cathode electrode is considered. However, when the cathode electrode is made thicker, since a transmittance of visible light is significantly reduced, the brightness of the completed organic EL element is lowered.

For this reason, in the optical semiconductor device of the present embodiment, as shown in FIG. 1, the vacuum ultraviolet light absorption layer 107 is provided on the cathode electrode 106. By this means, the vacuum ultraviolet light used in the film formation process by the optical CVD method is absorbed by the vacuum ultraviolet light absorption layer 107 when the encapsulating film is formed on the cathode electrode 106 by using the optical CVD method, thereby preventing the organic EL layer 105 from being damaged by the vacuum ultraviolet light. When the transmittance of the vacuum ultraviolet light to the organic EL layer becomes 10% or more, optical deterioration of the organic EL layer 105 becomes prominent. Therefore, in the present embodiment, the silicon oxynitride film is used for the member of the vacuum ultraviolet light absorption layer 107, thereby suppressing the transmittance of the vacuum ultraviolet light transmitting through the organic EL layer 105 to less than about 10%. More specifically, the vacuum ultraviolet light absorption layer 107 is composed of an insulating film that absorbs 90% or more of the vacuum ultraviolet light. In this manner, the optical deterioration of the organic EL layer 105 can be prevented without increasing the thickness of the cathode electrode 106.

As described above, in the present embodiment, in order to suppress the optical damage to the organic EL layer in the film formation process of the optical CVD film, the absorption layer of the vacuum ultraviolet light is formed on the organic EL layer by using the plasma CVD method before performing the optical CVD. By the light absorption layer thus formed, the optical damage to the organic EL layer by the vacuum ultraviolet light when forming the laminated encapsulating film can be significantly suppressed.

The details of the present embodiment will be described below with reference to FIGS. 1 to 7. First, as shown in FIG. 2, an insulating film 102 is formed on a prepared glass substrate 101. The insulating film 102 is formed by a plasma CVD method using TEOS and O₂ (oxygen) as source gas so as to have a thickness of, for example, 200 nm. Subsequently, after forming a laminated film of aluminum and indium tin oxide (ITO), the laminated film is processed to have a prescribed shape by a dry etching method using a photolithography technology, thereby forming an anode electrode 103.

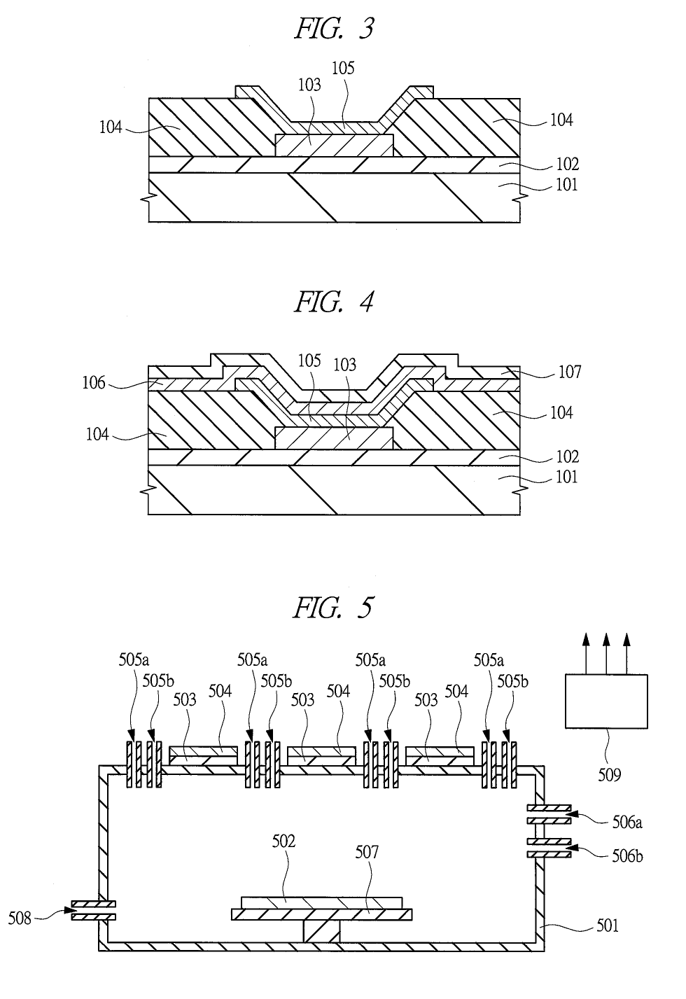

Next, as shown in FIG. 3, after a photosensitive polyimide film is formed on the anode electrode 103 and the insulating film 102, an opening in which a part of the upper surface of the anode electrode 103 is exposed is formed by an optical process, thereby forming a bank part 104 composed of the polyimide film. The opening has a tapered angle, and a width of the bottom of the opening is narrower than a width of the uppermost part of the opening. The reason why the opening is formed so as to spread upward from the upper surface of the exposed anode electrode 103 as described above is because an organic EL layer 105 formed on the anode electrode 103 and the opening of the bank part 104 in the subsequent process is formed without trouble. In other words, for example, when the opening has an inner wall vertical to the main surface of the glass substrate 101, since the organic EL layer 105 is formed along the inner wall of the opening and also formed so as to be bent at a right angle at the bottom and the upper part of the opening, it becomes difficult to form the organic EL layer 105 serving as an emission layer at a uniform precision. For this reason, the opening of the bank part 104 has a tapered angle, and the organic EL layer 105 can be formed on the opening with a gentle angle.

Thereafter, the organic EL layer 105 electrically connected to the anode electrode 103 is formed on the bottom of the opening of the bank part 104 by using a mask vapor deposition method. The organic EL layer 105 is made up of a hole injection layer, a hole transport layer, an emission layer, an electron transport layer, and an electron injection layer which are sequentially formed in this order from the anode electrode 103 side, and the laminated films will be collectively described as the organic EL layer 105 here. In the present embodiment, though a fluorescent low-molecular material is used for the organic EL layer 105, since the present invention is not an invention related to the organic EL layer, the detailed description of the material of the organic EL layer 105 will be omitted here.

Next, as shown in FIG. 4, after a cathode electrode 106 made of an Ag—Mg alloy with a thickness of 20 nm is formed on the bank part 104 and the organic EL layer 105 by using the mask vapor deposition method, a vacuum ultraviolet light absorption layer 107 made of a silicon oxynitride film is formed on the cathode electrode 106 by the plasma CVD method. In the present embodiment, an inductive coupled type ICP-CVD (Inductively Coupled Plasma-CVD) method using monosilane (SiH₄), nitrogen and oxygen as source gas is used for the formation of the vacuum ultraviolet light absorption layer 107, but there is no problem even if the vacuum ultraviolet light absorption layer 107 is formed by using other methods such as a capacitive coupled type CCP-CVD (Capacitively Coupled Plasma-CVD) method, a sputtering method or a vapor deposition method as long as neither thermal damage (about 100° C. or lower) nor plasma damage is given to the organic EL layer 105. In the present embodiment, the refractive index of the silicon oxynitride film serving as the vacuum ultraviolet light absorption layer 107 with respect to the light with the wavelength of 632.8 nm is set to 1.7, and the film thickness of the silicon oxynitride film is set to 150 nm. The light with the wavelength of 632.8 nm is a visible light generated by using a He—Ne gas laser device.

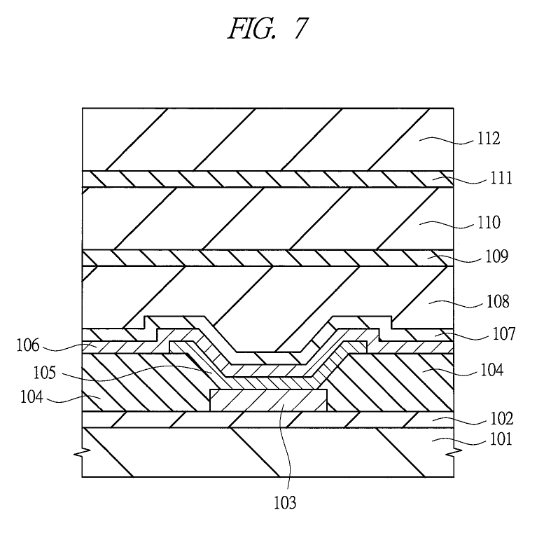

Next, by forming an encapsulating film having a laminated structure on the vacuum ultraviolet light absorption layer 107 by using a film formation device shown in FIG. 5, a structure shown in FIG. 7 is formed. Here, a buffer film and a barrier film are alternately laminated on the organic EL layer 105 in a plurality of layers in this order from the organic EL layer 105 side via the cathode electrode 106 and the vacuum ultraviolet light absorption layer 107. In other words, as shown in FIG. 7, a buffer film 108 with a thickness of 1000 nm, a barrier film 109 with a thickness of 150 nm, a buffer film 110 with a thickness of 1000 nm, a barrier film 111 with a thickness of 150 nm, and a buffer film 112 with a thickness of 1000 nm are sequentially formed in this order on the vacuum ultraviolet light absorption layer 107, thereby forming the encapsulating film composed of these buffer films 108, 110, and 112, and the barrier films 109 and 111.

Although the vacuum ultraviolet light absorption layer 107 is formed as a ground on which the buffer film 108 is formed, the surface of the ground has an uneven shape due to the opening of the bank part 104. Since the encapsulating film becomes a path of the light emitted from an organic EL element, diffusion and reflection of the light inside the encapsulating film need to be suppressed, and the encapsulating film is desired to have a flat upper surface parallel to the main surface of the glass substrate 101. Here, when the uneven shape of the ground is filled by forming the buffer film 108 showing the fluidity in its formation, the upper surface of the buffer film 108 can have a flat shape, and therefore, the upper surface and bottom surface of the buffer film and the barrier film formed thereon can be formed to have a flat shape parallel to the main surface of the glass substrate 101.

In addition to the uneven shape due to the opening, foreign matters such as etching residues or dusts formed on the glass substrate 101 before forming the buffer film 108 can be embedded by the buffer film 108. Therefore, it is possible to prevent a decrease of the brightness of the organic EL element due to the deformation of the interfaces between the films constituting the encapsulating film caused by the unevenness formed on the ground of the buffer film 108.

Furthermore, when the barrier film having lower embedding property than the buffer film is directly formed on the ground on which such foreign matters exist, it is considered that gaps where no barrier film is formed are generated on the ground surface directly below the foreign matters and on the side surfaces of the foreign matters. Since the barrier film is a moisture barrier film for preventing the intrusion of moisture, if gaps where the barrier film is not formed are partially generated, a tolerance of the organic EL element for the moisture is reduced, and the reliability of the optical semiconductor device is lowered. In contrast to this, when the buffer film 108 having the fluidity is formed before the barrier film 109 is formed as described above, the buffer film 108 can be formed so as to wrap up the foreign matters even when the foreign matters are formed on the surface of the ground. Therefore, it is possible to prevent the deterioration of the moisture barrier property of the organic EL element due to the gaps generated in the barrier film 109 formed on the buffer film 108.

Here, FIG. 5 shows a schematic diagram of the film formation device used for the formation of the encapsulating film of the present embodiment. The film formation device shown in FIG. 5 is made up of a vacuum exhaust mechanism 508, a reaction chamber 501 having a pressure control mechanism, a synthetic quartz window 503, a vacuum ultraviolet light lamp unit 504, remote plasma inlets 505a and 505b, gas inlets 506a and 506b, and a temperature controlled susceptor 507. Various types of radicals generated outside the device, for example, a nitrogen radical (N*), an oxygen radical (O*), an argon radical (Ar*), and the like are introduced from the remote plasma inlets 505a and 505b. In the present embodiment, the film is formed by using an Xe₂ excimer lamp (wavelength=172 nm) for the vacuum ultraviolet lamp unit 504. As shown in FIG. 5, the substrate (glass substrate) 502 to which the film is to be formed in the film formation process is disposed on the temperature controlled susceptor 507. Each configuration of the film formation device shown in FIG. 5 is controlled by a controller 509. More specifically, the controller 509 is a device having a role of controlling the flow rate (inflow) of the various types of radicals, the application of voltage to the vacuum ultraviolet light lamp unit 504, the temperature of the temperature controlled susceptor 507, and the like.

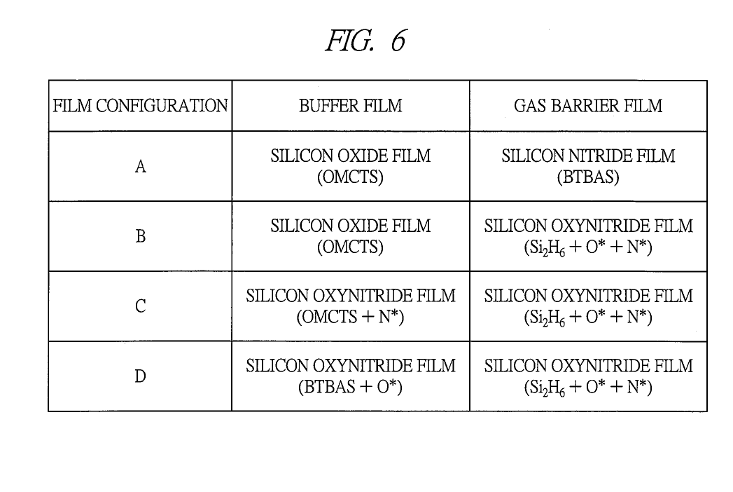

FIG. 6 shows a table for explaining a film configuration of the encapsulating film studied in the present embodiment. The source gasses used for the film formation are shown in the parentheses of FIG. 6. Although OMCTS (Octo methyl cyclotetrasiloxane) and BTBAS (Bis (tertiary butyl amino) silane) are illustrated as organic silicon sources, and Si₂H₆ (disilane) is illustrated as an inorganic silicon source, these source gasses are one of the preferred examples, and the source gasses used for the film formation of the encapsulating film are not limited to these gasses. As the gas for obtaining the same effect as that of OMCTS, for example, there are TEOS (Tetra ethoxy silane), HMDSO (Hexa methyl disiloxane), and the like. As the gas for obtaining the same effect as that of BTBAS, HMDS (Hexa methyl disilazane), HMCTSN (Hexa methyl cyclotrisilazane), and the like can also be used.

Here, as a combination of the film configurations of the buffer film and the barrier film constituting the encapsulating film, combinations of the film configurations A to D in the table of FIG. 6 are shown as examples.

The film configuration A shown in FIG. 6 is a configuration using a silicon oxide film for the buffer film and a silicon nitride film for the barrier film, respectively, and Patent Document 1 also describes the formation of the same film configuration. In the film configuration A, the silicon oxide film constituting the buffer film is formed by the optical CVD method using OMCTS, and the silicon nitride film constituting the barrier film is formed by the optical CVD method using BTBAS.

Further, the film configuration B shown in FIG. 6 is a configuration using a silicon oxide film for the buffer film and a silicon oxynitride film for the barrier film. In the configuration B, the silicon oxide film constituting the buffer film is formed by the optical CVD method using OMCTS, and the silicon oxynitride film constituting the barrier film is formed by the plasma assist optical CVD method using Si₂H₆, O* and N*. Note that O* and N* above represent the oxygen radical and the nitrogen radical, respectively.

Further, in both the film configuration C and the film configuration D shown in FIG. 6, a silicon oxynitride film is used for the buffer film and the barrier film, respectively. The plasma assist optical CVD method using Si₂H₆, O* and N* is similarly used for the barrier film in both the film configurations C and D, but the forming gas of the buffer film is different from each other. In the film configuration C, OMCTS and N* are used, and in the film configuration D, BTBAS and O* are used to form the silicon oxynitride film. In the film configurations C and D, OMCTS and BTBAS serving as the materials used to form the buffer film have a methyl group and a butyl group, respectively, and are both organic materials containing carbon. In contrast to this, Si₂H₆ (high order silane) gas serving as the material used to form the barrier film is an inorganic material containing no carbon (C).

A manufacturing method in the case where the four film configurations A to D shown in FIG. 6 are applied to the buffer film and the barrier film of FIG. 1 will be described below, and a result of comparison of the reflectance and the light extraction efficiency (brightness) of the encapsulating film formed by each of the film configurations will be shown below.

Each sample (substrate 502) on which the vacuum ultraviolet light absorption layer 107 has been formed through the process described with reference to FIG. 4 is conveyed on the temperature controlled susceptor 507 in the reaction chamber 501 the inside of which is maintained in vacuum as shown in FIG. 5, and is subjected to the film formation according to a prescribed sequence. At this time, the substrate 502 is controlled to a desired temperature by the temperature controlled susceptor 507. Since the organic EL layer has a property of being deteriorated by the heat of about 100° C. and unable to emit light, the substrate 502 is maintained at about 5° C. by the temperature controlled susceptor 507. When no plasma assist by the remote plasma is available in the film formation process, after the source gas is introduced into the reaction chamber 501 from the gas inlets 506a and 506b, and pressure adjustment is performed, the vacuum ultraviolet light is irradiated from the vacuum ultraviolet light lamp unit 504 to start the film formation. On the other hand, in the method using the plasma assist, after the source gas is introduced into the reaction chamber 501 from the gas inlets 506a and 506b, and pressure adjustment is performed, the vacuum ultraviolet light is irradiated on the substrate 502 from the vacuum ultraviolet light lamp unit 504, and at the same time, the plasma assist is performed, thereby starting the film formation. More specifically, during the irradiation of the vacuum ultraviolet light, the plasma irradiation using the remote plasma is performed.

In the film configuration A, OMCTS is introduced from the gas inlets 506a and an Xe₂ lamp is irradiated from the vacuum ultraviolet light lamp unit 504, thereby forming the buffer film 108 composed of the silicon oxide film on the substrate 502. Subsequently, BTBAS is introduced from the gas inlet 506b and the Xe₂ lamp is irradiated from the vacuum ultraviolet light lamp unit 504, thereby forming a barrier film 109 composed of the silicon nitride film on the substrate 502. In the same manner, a buffer film (silicon oxide film) 110, a barrier film (silicon nitride film) 111, and a buffer film (silicon oxide film) 112 are sequentially formed on the substrate 502 in this order.

In the film configuration B, OMCTS is introduced from the gas inlet 506a and the Xe₂ lamp is irradiated from the vacuum ultraviolet light lamp unit 504, thereby forming the buffer film 108 composed of the silicon oxide film on the substrate 502. Subsequently, Si₂H₆ is introduced from the gas inlet 506b, N* is introduced from the remote plasma inlet 505a, O* is introduced from the remote plasma inlet 505b, and the Xe₂ lamp is irradiated from the vacuum ultraviolet light lamp unit 504, thereby forming the barrier film 109 composed of the silicon oxynitride film on the substrate 502. In the same manner, the buffer film (silicon oxide film) 110, the barrier film (silicon oxynitride film) 111, and the buffer film (silicon oxide film) 112 are sequentially formed on the substrate 502 in this order.

In the film configuration C, OMCTS is introduced from the gas inlet 506a, N* is introduced from the remote plasma inlet 505a, and the Xe₂ lamp is irradiated from the vacuum ultraviolet light lamp unit 504, thereby forming the buffer film 108 composed of the silicon oxynitride film on the substrate 502. Subsequently, Si₂H₆ is introduced from the gas inlet 506b, N* is introduced from the remote plasma inlet 505a, O* is introduced from the remote plasma inlet 505b, and the Xe₂ lamp is irradiated from the vacuum ultraviolet light lamp unit 504, thereby forming the barrier film 109 composed of the silicon oxynitride film on the substrate 502. In the same manner, the buffer film (silicon oxynitride film) 110, the barrier film (silicon oxynitride film) 111, and the buffer film (silicon oxynitride film) 112 are sequentially formed on the substrate 502 in this order. When the buffer films 108, 110, and 112 are formed, O* may be introduced from the remote plasma inlet 505b together with the introduction of N* from the remote plasma inlet 505a.

In the film configuration D, BTBAS is introduced from the gas inlet 506a, O* is introduced from the remote plasma inlet 505b, and the Xe₂ lamp is irradiated from the vacuum ultraviolet light lamp unit 504, thereby forming the buffer film 108 composed of the silicon oxynitride film on the substrate 502. Subsequently, Si₂H₆ is introduced from the gas inlet 506b, N* is introduced from the remote plasma inlet 505a, O* is introduced from the remote plasma inlet 505b, and the Xe₂ lamp is irradiated from the vacuum ultraviolet light lamp unit 504, thereby forming the barrier film 109 composed of the silicon oxynitride film on the substrate 502. In the same manner, the buffer film (silicon oxynitride film) 110, the barrier film (silicon oxynitride film) 111, and the buffer film (silicon oxynitride film) 112 are sequentially formed on the substrate 502 in this order. When the buffer films 108, 110, and 112 are formed, O* may be introduced from the remote plasma inlet 505b together with the introduction of N* from the remote plasma inlet 505a.

The refractive index of each layer formed by the above-described method with respect to the light with the wavelength of 632.8 nm is as follows. The refractive indexes of the buffer films (silicon oxide films) of the film configurations A and B are 1.44, and the refractive index of the barrier film (silicon nitride film) of the film configuration A is 1.92. On the other hand, the refractive indexes of the buffer films (silicon oxynitride films) of the film configurations C and D are 1.65, and the refractive indexes of the barrier films (silicon oxynitride films) of the film configurations B, C, and D are 1.7.

From the above-described results, in the optical semiconductor device of the present embodiment, the film configuration C or D is adopted for the configuration of the buffer film and the barrier film shown in FIG. 1 instead of the film configurations A and B shown in FIG. 6. In other words, the film configurations C and D shown in FIG. 6 are the film configurations used in the present embodiment, and the film configurations A and B are the film configurations used for comparison examples. Therefore, in the organic EL element of the present embodiment, the buffer films 108, 110, and 112 and the barrier films 109 and 111 shown in FIG. 1 are all formed of the silicon oxynitride film formed by the optical CVD method using the plasma assist.

The composition and the refractive index (absorption coefficient) of the silicon oxynitride film in the present embodiment can be adjusted by a flow ratio of the silicon based source gas, the oxygen radical (O*), and the nitrogen radical (N*). Although an example in which an oxidation source is supplied as the oxygen radical has been described in the present embodiment, since oxygen has high degradation efficiency for the vacuum ultraviolet light (large quenching cross-section area), it is possible to form the silicon oxynitride film even if the oxidation source is supplied as oxygen gas instead of the oxygen radical. More specifically, by performing the adjustment of the flow ratio of each gas, the silicon oxynitride film having the desired composition and refractive index (absorption coefficient) can be formed. The method using the oxygen gas instead of the oxygen radical in this manner can be applied to, for example, the formation of the barrier films of the film configurations C and D of FIG. 6 and to the formation of the buffer film of the film configuration D.

Thereafter, by the known technology, the wirings (not shown) connected to the anode electrode 103 and the cathode electrode 106 shown in FIG. 7 are formed, respectively, thereby completing the major part of the organic EL element of the present embodiment.

A comparison result of the brightnesses obtained when the current is applied to the four types of organic EL elements having the buffer films and the barrier films of respective film configurations A to D shown in FIG. 6 under the same condition will be described below. First, when the comparison is made in the sample structure in which the vacuum ultraviolet light absorption layer 107 is formed as shown in FIG. 1, the sample showing the highest brightness is the samples of the film configurations C and D, and both of the samples have shown almost equal brightness. In contrast to this, the film configuration B serving as a comparison example can obtain the brightness of only 20% to 30% of the film configuration C, and the film configuration A serving as a comparison example can obtain the brightness of only 8% to 15% of the film configuration C.

Furthermore, the sample is left alone for a predetermined time in the environment of the relative humidity of 90% and the temperature of 80° C., and a variation of the brightness with respect to the initial brightness is compared. As a result, the brightness of the film configurations C and D is scarcely changed, but the brightness of the film configuration B is reduced to 90% to 95%, and the brightness of the film configuration A is reduced to 70% to 80%. As shown above, according to the optical semiconductor device of the present embodiment having the encapsulating film of the film configuration C or D, the light extraction efficiency (brightness) of the organic EL element can be improved, and the reliability for moisture can also be improved.

The example in which the moisture barrier film (barrier film) is formed by the optical CVD method using the remote plasma assist has been described in the present embodiment, but the same effect can be obtained even when the other film formation method is used from the viewpoint of the light extraction efficiency (refractive index control) or the moisture barrier property (film density). For example, if the ground, that is, the upper surface of the buffer film 108 is flattened by the formation of the buffer film 108 with high fluidity shown in FIG. 1, the barrier films 109 and 111 may be formed by the plasma CVD method which is inferior to the optical CVD method in unevenness coverage property. However, if the buffer film and the barrier film constituting the encapsulating film are continuously deposited by the same device as shown in the present embodiment, throughput can be significantly improved.

Further, although the refractive indexes of the buffer films 108, 110, and 112 formed by the optical CVD method using the remote plasma assist are 1.65 in the present embodiment, it is essential to set up a film composition in consideration of the other characteristics. Specifically, in the film formation by the optical CVD method using the organic silicon source, when the content of nitrogen in the film is increased, the refractive index is increased, but the fluidity of the film is deteriorated, and a film stress and the Young's modulus tend to increase. More specifically, while the buffer film is required to have a good flatness, a low stress for preventing the occurrence of a crack and the peeling of a film, and a low Young's modulus, a contradictory property such as the suppression of multiple reflection inside the laminated encapsulating film is also required. The inventors of the present invention have considered and studied the above-described points and confirmed that an excellent light extraction efficiency (brightness) can be obtained without causing a crack or a peeling of the film if the refractive index difference between the barrier film and the buffer film with respect to the light with the wavelength of 632.8 nm is within the range of 0.25 or less.

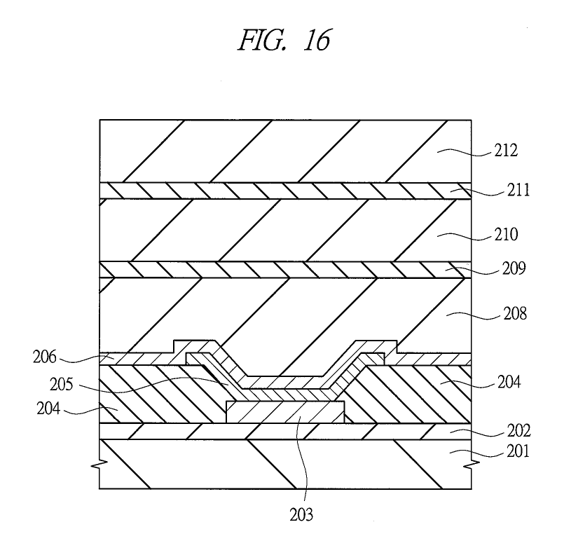

Next, a sample in which the vacuum ultraviolet light absorption layer 107 is formed as shown in FIG. 1 and a sample in which the vacuum ultraviolet light absorption layer is not formed as shown in FIG. 16 are compared. FIG. 16 is a cross-sectional view of the optical semiconductor device shown as a comparison example. Although both samples similarly have the encapsulating film of the film configuration A of FIG. 6, the organic EL element of the comparison example of FIG. 16 is different from the organic EL element of the present embodiment in that the ultraviolet light absorption layer is not formed on the cathode electrode 206. In other words, except that the ultraviolet light absorption layer is not formed, the organic EL element shown in FIG. 16 has the same structure as that of the organic EL element shown in FIG. 1.

Since the encapsulating film has the film configuration A shown in FIG. 6 in the sample shown in FIG. 1 in which the vacuum ultraviolet light absorption layer 107 is formed, its brightness is small compared with the film configurations C and D, but it can emit light. However, the sample shown in FIG. 16 in which the vacuum ultraviolet light absorption layer 107 is not formed scarcely emits light. This is because, in the forming process of the buffer film 208 which is the initial process of the encapsulating film formation, the vacuum ultraviolet light used in the optical CVD method transmits through the cathode electrode 206 and gives an optical damage to the organic EL layer 205. In contrast to this, since the vacuum ultraviolet light absorption layer 107 is provided immediately above the organic EL layer 105 in the present embodiment as shown in FIG. 1, the encapsulating film can be formed by the optical CVD method without giving the optical damage to the organic EL layer.

Although an example using the silicon oxynitride film for the member of the vacuum ultraviolet light absorption layer 107 has been shown in the present embodiment, the vacuum ultraviolet light absorption layer 107 is not always required to be the silicon oxynitride film, and it may be made up of the other members. According to the studies by the inventors of the present invention, if the transmittance of the vacuum ultraviolet light transmitting through the organic EL layer 105 is less than about 10%, the optical deterioration of the organic EL layer is scarcely observed. To be exact, since the cathode electrode on the organic EL layer absorbs 5% of the vacuum ultraviolet light, if the transmittance of the vacuum ultraviolet light transmitting through the organic EL layer becomes 5% or more, the organic EL layer suffers the optical damage, and is optically deteriorated.

Accordingly, if the film is an insulating film which absorbs 90% or more of the vacuum ultraviolet light and does not give the optical damage to the organic EL layer 105, the other type of film other than the silicon oxynitride film can be used. For example, even when aluminum oxide, aluminum nitride, aluminum oxynitride, or the like is used, the same effects can be obtained. However, a necessary film thickness needs to be set in consideration of the light absorption coefficient of the types of films to be used.

Further, the vacuum ultraviolet light absorption layer 107 is formed by the other plasma CVD device in the present embodiment, but it may be formed by the device shown in FIG. 5. For example, there is a method in which the Si₂H₆ gas is introduced from the gas inlet 506a, N* is introduced from the remote plasma inlet 505a, O* is introduced from the remote plasma inlet 505b, and the silicon oxynitride film is formed without performing the lamp irradiation by the vacuum ultraviolet light lamp unit 504. Since no light irradiation is performed, the film formation speed may be reduced, but since the Si₂H₆ gas reacts with the radical introduced from the remote plasma, the silicon oxynitride film can be formed by adjusting the gas flow ratio. In this case, since the silicon oxynitride film can be collectively formed by the same device as that of the encapsulating film, the effect of improving the throughput of the overall process and reducing the device investment cost is obtained.

As described above, in the organic EL element of the present embodiment, the buffer films 108, 110, and 112 and the barrier films 109 and 111 shown in FIG. 1 are formed to have the film configuration C or D shown in FIG. 6 so that the refractive index differences of each of the buffer film and the barrier film, the buffer film and the cathode electrode, and the buffer film and the adhesion layer are reduced. By this means, it is possible to suppress the multiple reflection of the light inside the encapsulating film and improve the light extraction efficiency (brightness) of the organic EL element.

As described above, the buffer film and the barrier film can be made of the silicon oxynitride film that is formed by the optical CVD method using the remote plasma assist. As a result, the refractive index difference between the buffer film and the barrier film can be reduced. In the ordinary optical CVD method not using the remote plasma assist, it is difficult to degrade the source gas having small quenching cross-section area such as ammonia gas or a nitrogen gas to take out nitrogen and introduce the nitrogen into a film to be formed. However, by using the film formation device as shown in FIG. 5 to supply the nitrogen radical or the like by using the remote plasma assist, the desired silicon oxynitride film can be formed.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, since the encapsulating film is formed by using the optical CVD method in the embodiment described above, it is necessary to prevent the organic EL layer from being damaged by the vacuum ultraviolet light used in the optical CVD method. In the embodiment described above, since the vacuum ultraviolet light absorption layer 107 is formed as shown in FIG. 1, the organic EL layer 105 can be prevented from being deteriorated to be incapable of emitting light due to the vacuum ultraviolet light irradiated at the time of forming the buffer films 108, 110, and 112 and the barrier films 109 and 111.

Although the optical semiconductor device in which the organic EL element and the encapsulating film thereof are formed has been shown as an example in the embodiment described above, it is of course possible to apply the encapsulating film to the organic EL display provided with a thin film transistor. For example, the organic EL display can be formed by providing a switching element made up of a thin film transistor between the glass substrate 101 and the insulating film 102 shown in FIG. 1 and connecting the switching element and the organic EL element.

Further, by forming the encapsulating film of the present invention on the front and back surfaces of the resin film or the resin substrate, dimensional fluctuation due to moisture absorption of the resin film or the resin substrate and the like can be suppressed. In addition, by combining the resin film or the resin substrate having the encapsulating film according to the present invention formed thereon with the organic EL display, a flexible organic EL display can also be formed. In this case, after the structure shown in FIG. 1 is formed, the glass substrate 101 is removed, and then, the resin substrate whose surface is covered with the encapsulating film having the same structure as those of the buffer film and the barrier film shown in FIG. 1 is adhered to the lower part of the anode electrode 103. Similarly, it is of course possible to apply the encapsulating film of the embodiment described above to organic EL illumination. The effect is significant particularly in the device structure in which the visible light passes through the encapsulating film like the present embodiment.

Further, although the cathode electrode is disposed on the organic EL layer and the anode electrode is disposed below the organic EL layer in the embodiment described above, it is also possible to inversely dispose the anode electrode on the organic EL layer and dispose the cathode electrode below the organic EL layer.

The manufacturing method of the optical semiconductor device of the present invention is widely utilized for the optical semiconductor device having the encapsulating film through which the visible light transmits.

What is claimed is:

1. An optical semiconductor device having a first electrode, an organic emission layer, and a second electrode formed on a substrate in this order from a main surface side of the substrate, and an encapsulating film provided on the substrate so as to cover the emission layer,
wherein the encapsulating film includes a laminated film obtained by alternately laminating a flattening film and a barrier film, and
wherein the flattening film and the barrier film include a silicon oxynitride film.

2. The optical semiconductor device according to claim 1,
wherein an upper surface of the first electrode is exposed from an opening of a first insulating film formed between the flattening film and the substrate, a bottom surface of the flattening film of a lowermost layer formed on the opening has an unevenness, and an upper surface of the flattening film of the lowermost layer is flat.

3. The optical semiconductor device according to claim 1,
wherein the flattening film includes a silicon oxynitride film containing carbon, and
wherein the barrier film includes an inorganic silicon oxynitride film.

4. The optical semiconductor device according to claim 1,
wherein the flattening film is formed by using an optical CVD method using a vacuum ultraviolet light and a plasma CVD method using remote plasma in combination.

5. The optical semiconductor device according to claim 1,
wherein the barrier film is formed by using an optical CVD method using a vacuum ultraviolet light and a plasma CVD method using remote plasma in combination.

6. The optical semiconductor device according to claim 1,
wherein the flattening film has lower Young's modulus than that of the barrier film, and the barrier film has higher film density and higher moisture barrier property than those of the flattening film.

7. The optical semiconductor device according to claim 1,
wherein a second insulating film absorbing vacuum ultraviolet light is formed between the organic emission layer and the encapsulating film.

8. The optical semiconductor device according to claim 7,
wherein the second insulating film is an insulating film absorbing 90% or more of the vacuum ultraviolet light.

9. A manufacturing method of an optical semiconductor device comprising the steps of:
(a) forming a first electrode on a substrate;
(b) forming an organic emission layer electrically connected to the first electrode on the first electrode;
(c) forming a second electrode electrically connected to the organic emission layer on the organic emission layer; and
(d) forming a silicon oxynitride film on the organic emission layer by an optical CVD method using a vacuum ultraviolet light,
wherein in the step (d), radical irradiation by remote plasma is performed during irradiation of the vacuum ultraviolet light.

10. The manufacturing method of the optical semiconductor device according to claim 9,
wherein in the step (d), the silicon oxynitride films are laminated in a plurality of layers, and a flattening film including one of the plurality of silicon oxynitride films and a barrier film including one of the plurality of silicon oxynitride films are alternately laminated on the organic emission layer in this order from an organic emission layer side.

11. The manufacturing method of the optical semiconductor device according to claim 10,
wherein in the step (d), the flattening film is formed of an organic material having carbon, and the barrier film is formed of only an inorganic material.

12. The manufacturing method of the optical semiconductor device according to claim 10,
wherein the flattening film is a film showing fluidity in a formation process, and the barrier film has higher film density and higher moisture barrier property than those of the flattening film.

13. The manufacturing method of the optical semiconductor device according to claim 9, further comprising, after the step (a) and before the step (b), a step of forming a first insulating film on the substrate and then forming an opening in the first insulating film, thereby exposing an upper surface of the first electrode.

14. The manufacturing method of the optical semiconductor device according to claim 9,
wherein in the step (d), at least one of nitrogen radical and oxygen radical and organic silicon gas are used as a source gas to form the silicon oxynitride film.

15. The manufacturing method of the optical semiconductor device according to claim 9,
wherein in the step (d), one of oxygen radical and oxygen gas, high order silane gas, and nitrogen radical are used as a source gas to form the silicon oxynitride film.

16. The manufacturing method of the optical semiconductor device according to claim 9, further comprising, before the step (d), a step of forming a second insulating film absorbing 90% or more of the vacuum ultraviolet light on the organic emission layer.
